(19) United States
(12) Patent Application Publication
(10) Pub. No.: US 2008/0176375 A1
(43) Pub. Date: Jul. 24, 2008

(54) METHOD FOR FORMING A DIELECTRIC LAYER

(75) Inventors: Elke Erben, Dresden (DE); Stephan Kudelka, Dresden (DE); Alfred Kersch, Putzbrunn (DE); Angela Link, Munchen (DE); Matthias Patz, Dresden (DE); Jonas Sundqvist, Dresden (DE)

Correspondence Address: COATS & BENNETT/QIMONDA, 1400 CRESCENT GREEN, SUITE 300, CARY, NC, 27518, US

(73) Assignee: QIMONDA AG, Munchen (DE)

(21) Appl. No.: 11/970,654

(22) Filed: Jan. 8, 2008

(30) Foreign Application Priority Data
Jan. 19, 2007 (DE) 10 2007 002 962.6

(51) Int. Cl. H01L 21/31; H01L 21/02

(52) U.S. Cl. 438/386; 438/785; 257/E21.24; 257/E21.008

(57) ABSTRACT

The present invention relates to a deposition of a dielectric layer. On a substrate having a structured area a crystallization seed layer for a dielectric layer is deposited via an atomic layer deposition technique employing a first and a second precursor on the structured area of the substrate. The first pre-cursor is a compound having the constitutional formula M¹(R¹Cp)ₓ(R²)₄₋ₓ, wherein M¹ is one of hafnium and zirconium, Cp is cyclopentadienyl, R¹ is independently selected of methyl, ethyl and alkyl, R² is independently selected of hydrogen, methyl, ethyl, alkyl and alkoxyl, and x is one or two. The dielectric layer is deposited on the crystallization seed layer via an atomic layer deposition technique employing a third and a forth precursor wherein the third pre-cursor being a compound having the constitutional formula M² R³ R⁴ R⁵ R⁶, wherein M² is one of hafnium or zirconium and R³, R⁴, R⁵, and R⁶ are independently selected of alkyl amines.

### BACKGROUND OF THE INVENTION

1. Field of the Invention

The present invention relates to a method for forming a dielectric layer.

2. Description of the Related Art

Although in principle applicable to arbitrary integrated semiconductor structures, the following invention and the underlying problems will be explained with respect to integrated DRAM memory circuits in silicon technology.

Memory cells of a DRAM device each comprise a capacitor for storing information encoded as electric charge retained in the capacitor. A reliable operation of the memory cells demands for a minimal capacitance of the capacitors and a sufficiently long retention time of the charge in the capacitors.

There is a major interest to further reduce the lateral dimensions of structures of a DRAM, at present 45 nm are envisaged. Therefore, it becomes necessary to compensate the shrinking lateral dimensions of the capacitors by increasing the k-value of the dielectric layer. The use of high k-dielectric layers demands for development of new deposition techniques, which allow control of the crystal structure of the dielectric materials and an efficient deposition of the materials.

### BRIEF SUMMARY OF THE INVENTION

According to a first aspect of the invention, the following steps are performed:

providing a substrate having a structured area,

depositing a crystallization seed layer for a dielectric layer via an atomic layer deposition technique employing a first and a second precursor on the structured area of the substrate, the first pre-cursor being a compound having the constitutional formula M¹(R¹Cp)ₓ(R²)₄₋ₓ, wherein M¹ is one of hafnium and zirconium, Cp is cyclopentadienyl, R¹ is independently selected of hydrogen, methyl, ethyl and alkyl, R² is independently selected of hydrogen, methyl, ethyl, alkyl, alkoxyl, and halogen, and x is one or two, and;

depositing the dielectric layer on the crystallization seed layer via an atomic layer deposition technique employing a third and a forth precursor wherein the third pre-cursor being a compound having the constitutional formula M² R³ R⁴ R⁵ R⁶, wherein M² is one of hafnium and zirconium and R³, R⁴, R⁵, R⁶ are independently selected of alkyl amines.

According to a second aspect the following steps are performed:

providing a substrate

forming a trench in the substrate;

forming a first electrode in or on the trench side walls;

depositing a crystallization seed layer for a dielectric layer via an atomic layer deposition technique employing a first and a second precursor at a temperature in the range of 300° C. to 500° C. on the first electrode, the first pre-cursor being a compound having the constitutional formula M¹(R¹Cp)₂(R²)₂, wherein M¹ is one of hafnium and zirconium, Cp is cyclopentadienyl, R¹ is independently selected of hydrogen, methyl, ethyl and alkyl, R² is independently selected of hydrogen, methyl, ethyl, alkyl, alkoxyl and halogen,

depositing the dielectric layer on the crystallization seed layer via an atomic layer deposition technique employing a third and a forth precursor wherein the third pre-cursor being a compound having the constitutional formula M² R³ R⁴ R⁵ R⁶, wherein M² is one of hafnium or zirconium and R³, R⁴, R⁵, and R⁶ are independently selected of alkyl amines; and

depositing a counter electrode on the dielectric layer in the trench.

The crystal growth of hafnium oxide and zirconium oxide and dielectrics containing at least one of these oxides can be effectively controlled by a starting seed layer. The quality of the seed layer is, however, crucial for outcome of the deposition. It could be demonstrated that precursors based on cyclopentadienyl compounds allow a conformal deposition of the seed layer in a desired crystal structure.

The crystallization seed layer can be deposited at a temperature in the range of 300° to 500° C.

The alkyl amines R³, R⁴, R⁵, R⁶ can be one of the group of methyl amines and ethyl amines. An amine is a functional group of the formula NR⁷R⁸; connected via the nitrogen. Compounds of the formula M² R⁹ wherein M² is a metal and R⁹ an amine may be called metal-amide. This is not be confused with compounds comprising an amide as functional group. An amide is of the formula (CO) NR¹⁰R¹⁰; connected via the carbon of the carbonyl-group (CO). The metal-amides in the context of this application refer to compounds of the type without an amide as functional group that is connected to the metal.

A dopant material may be applied to the dielectric layer during reacting the first precursor and the second pre-cursor, the dopant material is at least one of the group of aluminium, rare earth metal, titanium, hafnium, tantalum, strontium, barium, scandium, yttrium, lanthanum, niobium, bismuth, calcium and cerium.

The concentration of the dopant material in the dielectric layer may be in the range of 1-50 atomic percent preferred 1-20 atomic percent, relative to the transition metal concentration.

A fifth precursor can be used additional to the third precursor, the fifth precursor is selected of at least one of the formula of Al(CH₃)₃, Si(NR¹₂)₄, SiH(NR¹₂)₃, SiH₂(NR¹₂)₂, wherein R¹ is independently selected from methyl and ethyl. The fifth precursor can be applied in parallel to the third precursor. In an alternative the deposition using the third precursor is interrupted and one or monolayers are deposited via the fifth precursor.

### DESCRIPTION OF THE DRAWINGS

In the Figures:

FIGS. 1-3 show steps of one embodiment of a method for forming a dielectric layer.

In the Figures, like numerals refer to the same or similar functionality throughout the several views.

### DETAILED DESCRIPTION OF THE INVENTION

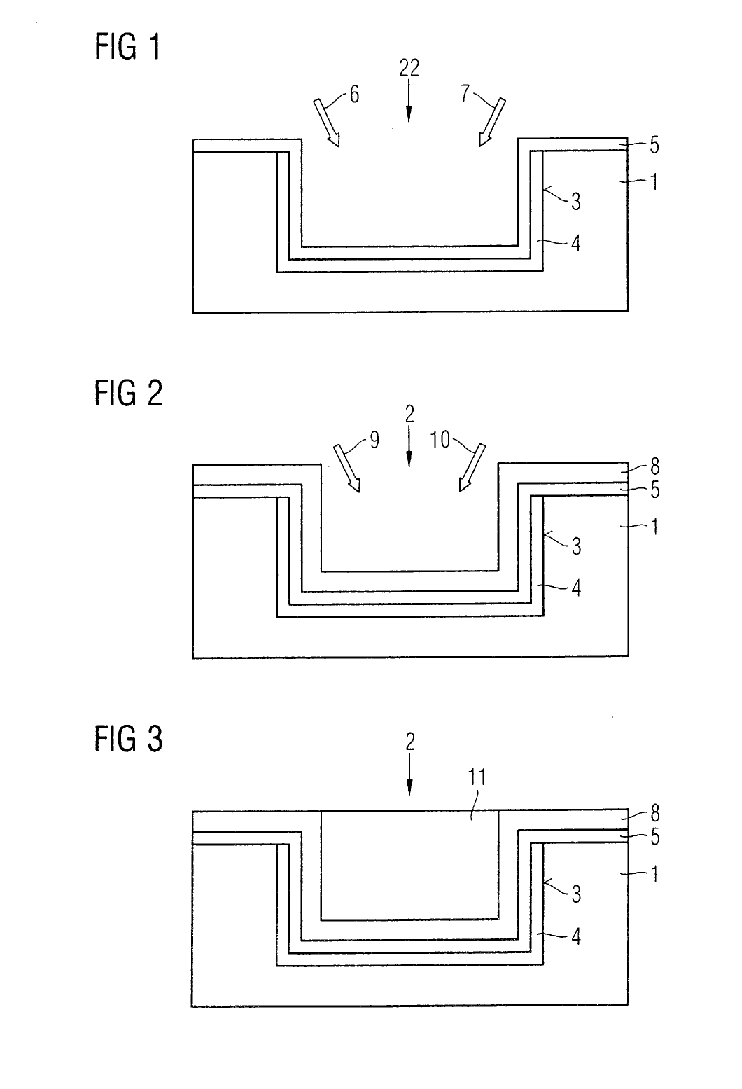

A preferred embodiment of the deposition of a dielectric material will be exemplarily described along with FIGS. 1 to 3, which show the manufacturing of a capacitor structure.

In a silicon substrate 1 a trench 2 is formed. Along side walls 3 of the trench 2 an electrode 4 is formed. The electrode 4 may be formed by depositing a conductive material, e.g. titanium nitride, titanium carbon nitride, titanium silicon nitride, titanium, carbon, tantalum nitride, tantalum carbide, tantalum carbon nitride, tantalum silicon nitride, tungsten, ruthenium and/or platinum. The electrode 4 can be formed by implanting a dopant material into the silicon substrate, too.

A dielectric layer is deposited in at least two steps. An initial step is shown in FIG. 1. A crystallization seed layer 5 of hafnium oxide is deposited in the trench 2 on the electrode 4. The crystallization seed layer 5 is formed with a cubic crystallization structure. This is achieved by an atomic layer deposition technique using as first precursor for instance bis-(methyl cyclopentadienyl) hafnium dimethyl, (Me Cp)₂ Hf Me₂ as first precursor 6 (Me designates methyl and Cp designates cyclopentadienyl) or other precursors based on cyclopentadienyl functional groups. The second precursor 7 is ozone, O₃ for oxidizing the chemically adsorbed first precursor and generating hydroxyl-groups at the surface of the deposited hafnium oxide. The precursors are alternatingly introduced into a reaction chamber, in which the silicon substrate 1 is placed. The temperature chosen for the deposition can be in the range of 300° C. to 500° C., preferably in the range of 400° C. to 450° C. The deposition is continued until a thickness of the deposited crystallization seed layer 5 is in the range of 1 nm to 2 nm is achieved.

A pulse of the first pre-cursor injected into a reaction chamber for single wafer processing is of a duration of about 1-60 s and into a reaction chamber for batch processing, i.e. for parallel processing of a plurality of wafer, of about 30-180 s, for instance. It is understood that the duration of the pulses depends on the wafer to be processed and the reaction chambers used.

A typical partial pressure of the first pre-cursor can be in the range of 10-400 Pa (about 0.1-3 torr). The necessary flow rate of the first pre-cursor depends on the reaction chamber employed, a typical value may be in the range of 50 sccm. An additional purge gas, preferably an inert gas like argon, is introduced into the reaction chamber along with the first pre-cursor. The purge gas ensures a transport of the first pre-cursor to the wafer and a removal of the first pre-cursor, so that the first precursor reacts with the wafer only during a well defined time slot. The oxidant may be applied without a purge gas.

On the crystallization layer 5 a dielectric layer 8 is deposited via a second atomic layer deposition technique using a third precursor 9 and a forth precursor 10 (FIG. 2). The third precursor may be tetrakisetylmethylamido-hafnium, Hf[N(CH₃)(C₂H₅)]₄, for instance. The application of the third precursor, pulse duration, pressure and purge gas is chosen in the same range as of the above first precursor. The temperature in the reaction chamber can be in the range of 200° C. to 300° C. The deposition of the dielectric 8 is continued until a thickness providing desired electric properties is achieved. A typical thickness of the dielectric layer 8 is for instance in the range of 5 nm to 10 nm.

The capacitor structure is finished by filling the trench 2 with a counter electrode 11. The counter electrode 11 is formed of highly doped poly-crystalline silicon. The counter electrode 11 can be formed of a conductive metal containing compound, e.g. titanium nitride, titanium carbon nitride, titanium silicon nitride, titanium, carbon, tantalum nitride, tantalum carbide, tantalum carbon nitride, tantalum silicon nitride, tungsten, ruthenium and/or platinum as well. The counter electrode can be of mixed compositions like a thin titanium nitride film and a doped polysilicon fill, as well.

In a further preferred embodiment a capacitor having a hafnium aluminium oxide layer is formed. A first electrode in a trench is provided. A crystallization seed layer of hafnium oxide is deposited as described herein above on the first electrode. On the crystallization layer 5 a dielectric layer comprising hafnium aluminium oxide is deposited. Alternatingly, hafnium oxide and aluminium oxide are deposited via atomic layer deposition techniques. The stoichiometric ratio of aluminium and hafnium in the hafnium aluminium oxide compound is controlled by the amount of monolayers formed with hafnium oxide and the amount of monolayers formed with aluminium oxide. Aluminium oxide can be deposited by use of trimethylaluminium, Al(CH₃)₃ and ozone as precursors. The counter electrode is formed as hereinabove.

A further embodiment is based on one of the above embodiments. The crystallization seed layer is deposited by use of bis-(methyl cyclopentadienyl) hafnium dimethyl or other cyclopentadienyl based precursors and ozone. Additionally a dopant material is deposited into the formed hafnium oxide. A dopant used is silicon in a concentration 1-20 atomic percent relative to hafnium, for instance. The dopant stabilizes the formation of a cubic crystallographic structure against the formation of monoclinic crystallographic structures.

The above embodiments illustrate the formation of a dielectric layer comprising hafnium oxide or hafnium aluminium oxide by use of biscyclopentadienyl-hafnium. All embodiments can be realized with zirconium instead of hafnium, i.e. zirconium oxide or zirconium aluminium oxide is formed as dielectric layer. Biscyclopentadienyl-zirconium is used as first precursor.

The compounds hafnium aluminium oxide and zirconium aluminium oxide can be replaced by hafnium silicon oxide and zirconium silicon oxide, respectively. The fifth precursor used can be tetrakis (dimetyl amido)-silicone Si[N(CH₃)₂]₄; tris dimethyl amido silane, SiH(N(CH₃)₂]₃; bis dimethyl amido silane, SiH₂[N(CH₃)₂]₂ or any other silicon alkyl amide. The deposition of the silicon oxide using the above silicon compounds is preferably performed at 200° C. to 300° C.

The oxidizing precursor in the above embodiments is ozone. All atomic layer deposition techniques can be performed with bimolecular oxygen O₂; water H₂O; ammonia NH₃; and hydrazine N₂H₄ as substitute of ozone independently in the formation of the seed layer and the dielectric layer.

Although the present invention has been described with reference to a preferred embodiment, it is not limited thereto, but can be modified in various manners which are obvious for persons skilled in the art. Thus, it is intended that the present invention is only limited by the scope of the claims attached herewith.

The above embodiments all referred to manufacturing a capacitor structure the present invention, however, can be used for the formation of all kinds of dielectric layers, e.g. gate dielectrics, or even for filling of isolation trenches.

1. A method for forming a dielectric layer, comprising the steps:
providing a substrate having a structured area,
depositing a crystallization seed layer for a dielectric layer via an atomic layer deposition technique employing a first and a second precursor on the structured area of the substrate, the first pre-cursor being a compound having the constitutional formula M¹(R¹Cp)ₓ(R²)₄₋ₓ, wherein
M¹ is one of hafnium and zirconium,
Cp is cyclopentadienyl,
R¹ is independently selected of methyl, ethyl and alkyl,
R² is independently selected of hydrogen, methyl, ethyl, alkyl, alkoxyl, and halogen, and
x is one or two, and;
depositing the dielectric layer on the crystallization seed layer via an atomic layer deposition technique employing a third and a forth precursor wherein the third precursor being a compound having the constitutional formula M² R³ R⁴ R⁵ R⁶, wherein
M² is one of hafnium or zirconium and
R³, R⁴, R⁵, and R⁶ are independently selected of alkyl amines.

2. The method according to claim 1, wherein the crystallization seed layer is deposited at a temperature in the range of 300° to 500° C.

3. The method according to claim 2, wherein the alkyl amine is one of the group of methyl amine and ethyl amine.

4. The method according to claim 1, wherein a dopant material is applied to the dielectric layer during reacting the first pre-cursor and the second pre-cursor, the dopant material consisting of the group of silicon, aluminium, rare earth metal, titanium, hafnium, tantalum, strontium, barium, scandium, yttrium, lanthanum, niobium, bismuth, calcium and cerium.

5. The method according to claim 4, wherein the concentration of the dopant material in the dielectric layer is in the range of 1-20 atomic percent relative to the transition metal.

6. The method according to claim 1, wherein a fifth precursor is used additional to the third precursor, the fifth precursor is selected of at least one of the formula of Al(CH₃)₃, Si(NR¹₂)₄, SiH(NR¹₂)₃, SiH₂(NR¹₂)₂, wherein R¹ is independently selected from methyl and ethyl

7. A method for forming a capacitor, comprising the steps:
providing a substrate having a structured area;
forming a trench in the substrate;
forming a first electrode in or on the trench side walls;
depositing a crystallization seed layer for a dielectric layer via an atomic layer deposition technique employing a first and a second precursor at a temperature in the range of 300° C. to 500° C. on the first electrode, the first pre-cursor being a compound having the constitutional formula M¹(R¹Cp)₂(R²)₂, wherein
M¹is one of hafnium and zirconium,
Cp is cyclopentadienyl,
R¹ is independently selected of methyl, ethyl and alkyl,
R² is independently selected of hydrogen, methyl, ethyl, alkyl, alkoxyl and halogen,
depositing the dielectric layer on the crystallization seed layer via an atomic layer deposition technique employing a third and a forth precursor wherein the third precursor being a compound having the constitutional formula M² R³ R⁴ R⁵ R⁶, wherein
M² is one of hafnium or zirconium and
R³, R⁴, R⁵, and R⁶ are independently selected of alkyl amines; and depositing a counter electrode on the dielectric layer in the trench.
